(19) United States
(12) Patent Application Publication
(10) Pub. No.: US 2024/0421002 A1
(43) Pub. Date: Dec. 19, 2024

(54) INTEGRATED CIRCUIT DEVICE WITH MULTI-LENGTH GATE ELECTRODE

(71) Applicant: Intel Corporation, Santa Clara, CA (US)

(72) Inventors: Hwichan Jun, Portland, OR (US); Edward Yeh, San Jose, CA (US); Robin Chao, Portland, OR (US)

(73) Assignee: Intel Corporation, Santa Clara, CA (US)

(21) Appl. No.: 18/333,758

(22) Filed: Jun. 13, 2023

(51) Int. Cl. H01L 21/8234; H01L 27/088

(52) U.S. Cl. CPC H01L 21/823456; H01L 21/823481; H01L 27/0886

(57) ABSTRACT

An IC device includes a gate electrode having multiple lengths. The length of a first portion of the gate electrode, which is over a channel region in a semiconductor structure, may be longer (e.g., about 0.5-3 nm longer) than the length of a second portion of the gate electrode, which is over a channel region in another semiconductor structure. The pitches at the two portions of the gate electrode may be the same or substantially similar. The lengths of the gate electrode can be differentiated by using dry clean based removal of a dielectric material surrounding the semiconductor structures. A larger amount of the dielectric material may be removed at a first region than a second region so that the gap at the first region can be longer than the gap at the second region. A conductive material may be provided to fill the gaps to form the gate electrode.

### BACKGROUND

Integrated circuit (IC) fabrication usually includes two stages. The first stage is referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

Standard cell methodology is a popular method of designing IC devices, such as application-specific ICs. A standard cell may provide a logic function (e.g., AND, OR, XOR, etc.), storage function (e.g., flipflop, latch, etc.), other types of functions, or some combination thereof. A standard cell usually includes a group of transistors and interconnect structures, such as a group of parallel gate electrodes that are stacked over each other along a horizontal axis of the standard cell. The width of a standard cell may depend on the number of gate electrodes along the horizontal axis of the standard cell. The distance between two immediately adjacent gate electrodes along the horizontal axis of the standard cell may be referred to as the contacted poly pitch (CPP).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of an IC device with a multi-length gate electrode, according to some embodiments of the disclosure.

FIG. 2 illustrates an IC device with a FEOL section with a multi-length gate electrode and a BEOL section, according to some embodiments of the disclosure.

FIGS. 3A and 3B are cross-sectional views of an IC device with a multi-length gate electrode, according to some embodiments of the disclosure.

FIG. 4 is a top view of an IC device with a g multi-length gate electrode, according to some embodiments of the disclosure.

FIGS. 5A-5L illustrate a process of fabricating an IC device with a multi-length gate electrode, according to some embodiments of the disclosure.

FIGS. 6A-6B are top views of a wafer and dies that may facilitate one or more IC devices with multi-length gate electrodes, according to some embodiments of the disclosure.

FIG. 7 is a side, cross-sectional view of an example IC package that may include one or more IC devices with multi-length gate electrodes, according to some embodiments of the disclosure.

FIG. 8 is a cross-sectional side view of an IC device assembly that may include components having one or more IC devices with multi-length gate electrodes, according to some embodiments of the disclosure.

FIG. 9 is a block diagram of an example computing device that may include one or more components with one or more IC devices with multi-length gate electrodes, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

The dimension of a gate electrode in a direction along the horizontal axis of a standard cell is usually referred to as the length of the gate electrode, or gate length Lg. The gate length may be a distance between the source region and a drain region of a transistor. Modulation of gate length in the same CPP is usually done by modifying the thickness of self-aligned double patterning (SADP) spacer (also referred to as “gate spacer”). However, spacer modulation can create more complexity in the SADP process. Spacer modulation also has the limitation of minimum thickness gap. It can also cause source-drain opening width differences, which can result in variation in epitaxial growth. A solution is to use additional thin spacer deposition to increase gate length. However, adding a thin spacer can limit the minimum Lg increment due to the lower-thickness limit of the spacer deposition process. Another solution is to use trim (e.g., etch) process to thin down SADP spacer to reduce gate length. However, SADP spacer trim can cause significant increase of the SADP spacer thickness variation, and in return can cause Lg variation.

Embodiments of the present disclosure may improve on at least some of the challenges and issues described above by providing IC devices including multi-length gate electrodes. An example multi-length gate electrode has two or more different lengths. For instance, a portion of the multi-length gate electrode has a length that is greater than another portion of the multi-length gate electrode. The length difference may be facilitated by a dry clean based spacer thinning process. For instance, more dry clean steps in the spacer thinning process may be taken to get a larger gate length, versus a smaller gate length gets less dry clean steps. Etch selectivity of the dry clean based spacer thinning process can control the consumption of the sidewall of the gate spacer. Block patterning may be used to determine the etch area for each removal step.

In various embodiments of the present disclosure, an IC device may include a gate electrode having multiple lengths. For instance, the length of a first portion of the gate electrode is greater than the length of a second portion of the gate electrode. The first portion of the gate electrode may be over a channel region in a semiconductor structure in the IC device. The second portion of the gate electrode may be over a channel region in another semiconductor structure in the IC device. The differences between two lengths of the gate electrode may be in a range from approximately 0.5 nanometer (nm) to approximately 3 nm. The distance from the first portion of the gate electrode to another gate electrode (e.g., the gate pitch) may be the same or substantially similar as the distance from the second portion of the gate electrode to the other gate electrode. A dimension of the shallow trench isolation (STI) region under the first portion of the gate electrode may be smaller than the corresponding dimension of the STI region under the second portion of the gate electrode. Additionally or alternatively, a dimension of a gate insulator between the first portion of the gate electrode and the semiconductor structure may be smaller than the corresponding dimension of a gate insulator between the second portion of the gate electrode and the other semiconductor structure.

In some embodiments, the IC device may be formed by forming the semiconductor structures, e.g., over a substrate. A semiconductor structure may be a planar structure or non-planar structure (e.g., fin, nanoribbon, etc.). Gate spacers may be formed to wrap around each semiconductor structure at least partially. A gate spacer includes a dielectric material, such as oxide. There may be an open trench between two adjacent semiconductor structures. A surface of the gate spacer may face the semiconductor structure, and the opposing surface of the gate spacer may face the open trench. The length of the open trench can be modulated by controlling how much dielectric material is to be removed from the gate spacer by using dry clean. In the first removal step of the spacer thinning process, dry clean is applied to a target area of the gate spacer. In a subsequent removal step of the spacer thinning process, dry clean is applied to a part of the target area but not to the rest of the target area. That way, the part of the gate space that went through multiple removal steps would be thinner than the rest of the gate space. Such a spacer thinning process can result in multiple lengths of the open trench. After the removal process, a conductive material may be provided to fill the open trench to form at least part of the gate electrode. As the open trench has multiple lengths, the gate electrode can have multiple lengths.

The removal process in the present disclosure can enable Lg modulation in the fabrication flow without causing variation in the source-drain trench width. Also, the present disclosure can enable more precise Lg control (e.g., below approximately 2 nm) by using inner sidewall of spacer trim. There is also no complication of SADP, yielding better variable control of dummy poly backbone patterning.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of field-effect transistors (FETs), designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” or the phrase “A or B” means (A), (B), or (A and B). For the purposes of the present disclosure, the phrase “A, B, and/or C” or the phrase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

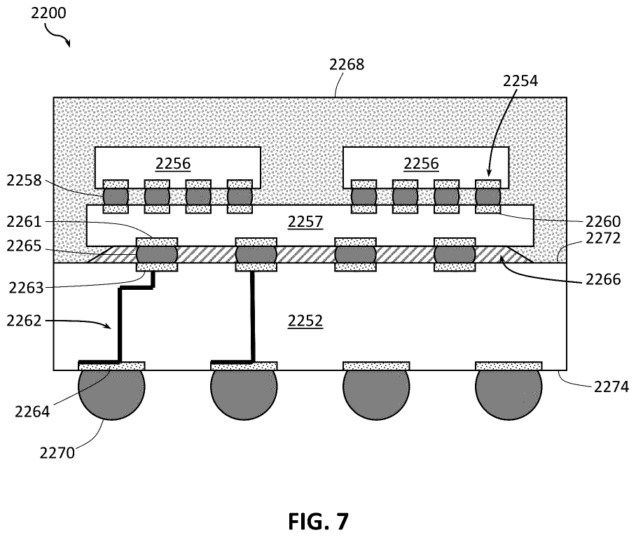

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with multi-length gate electrodes as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with multi-length gate electrodes as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

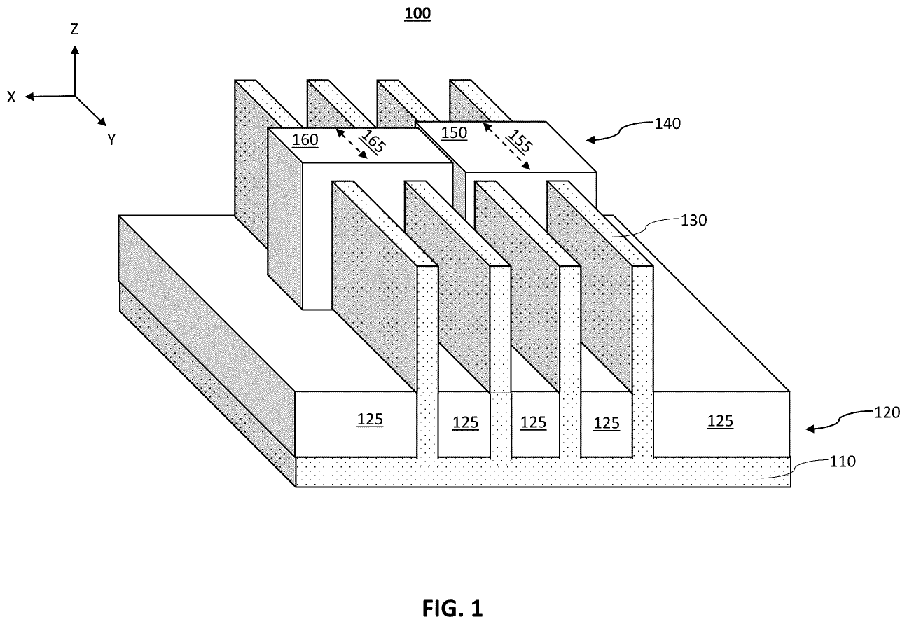

FIG. 1 is a perspective view of an IC device 100 with a multi-length gate electrode 140, according to some embodiments of the disclosure. The IC device 100 also includes a support structure 110, an dielectric layer 120, and a plurality of semiconductor structures 130 (individually referred to as “semiconductor structure 130”). For the purpose of illustration, not all components of the IC device 100 are shown in FIG. 1. The IC device 100 may include different, fewer, or more components. For instance, the IC device 100 may include gate insulator or spacer, which is not shown in FIG. 1.

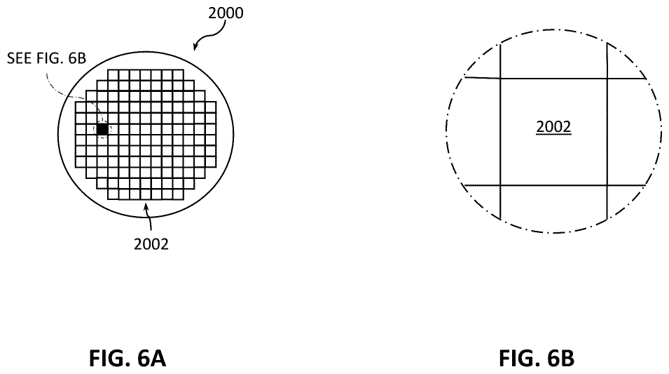

The support structure 110 may be any suitable structure, such as a substrate, a die, a wafer, or a chip, based on which transistors can be built. The support structure 110 may, e.g., be the wafer 2000 of FIG. 6A, discussed below, and may be, or be included in, a die, e.g., the singulated die 2002 of FIG. 6B, discussed below. In some embodiments, the support structure 110 may be a semiconductor substrate composed of semiconductor material systems including, for example, N-type or P-type materials systems, and, in some embodiments, the channel region, described herein, may be a part of the support structure 110. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 170, may be built on the support structure 110.

Although a few examples of materials from which the support structure 110 may be formed are described here, any material that may serve as a foundation upon which an IC may be built falls within the spirit and scope of the present disclosure. In various embodiments, the support structure 110 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 110 may provide material “support” in that, e.g., the IC devices/structures described herein are build based on the semiconductor materials of the support structure 110. However, in some embodiments, the support structure 110 may provide mechanical support.

The dielectric layer 120 is over various portions of the support structure 110 along the Z axis. The dielectric layer 120 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on. The dielectric layer 120 includes a plurality of dielectric structures 125 (individually referred to as “dielectric structure 125”). Each dielectric structure 125 is over a respective portion of the support structure 110 along the Z axis. A dielectric structure 124 may be between two semiconductor structures 130 along the X axis. A dielectric structure 125 may be an STI structure that can provide electrical isolation between neighboring transistors. A dielectric structure 125 may be formed by etching a shallow trench into a substrate and filling the shallow trench with a dielectric material.

The semiconductor structures 130 are over the support structure 110. In the embodiments of FIG. 1, the semiconductor structures 130 have a fin shape with a longitudinal axis substantially parallel to the Y axis and a transverse cross-section substantially parallel to the X-Z plane. A dimension of a semiconductor structure 130 along the Y axis may be greater than a dimension of the semiconductor structure 130 in another direction. The semiconductor structures 130 are arranged parallel to each other and are stacked in a direction along the X axis. Two adjacent semiconductor structures 130 are partially separated by the dielectric structure 125 between the two semiconductor structures 130. In other embodiments, a semiconductor structure 130 may have a different shape, e.g., nanoribbon, other non-planar shapes, or a planar shape.

A semiconductor structure 130 may provide the source region, channel region, and drain region of at least one transistor. A channel region of a transistor may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where a transistor is an NMOS (N-type metal oxide semiconductor) transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 10¹⁵ dopant atoms per cubic centimeter (cm⁻³), and advantageously below 1013 cm⁻³. These materials may be amorphous or polycrystalline, e.g., having a crystal grain size between 0.5 nanometers and 100 nanometers.

For some example P-type transistor embodiments (i.e., for the embodiments where a transistor is a PMOS (P-type metal oxide semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 1013 cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, n- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region and drain region in a transistor are connected to the channel region. The source region and drain region may each include a semiconductor material with dopants. In some embodiments, the source region and drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1.10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 1013 cm⁻³. Depending on the context, the term “S/D terminal” may refer to a S/D region or a S/D contact or electrode of a transistor.

The multi-length gate electrode 140 is over the dielectric layer 120. In FIG. 1, the multi-length gate electrode 140 wraps around the semiconductor structures 130. The multi-length gate electrode 140 and the semiconductor structures 130 may form gate-all-around transistors. The multi-length gate electrode 140 has a longitudinal axis that is substantially parallel to the X axis. The multi-length gate electrode 140 has two portions: a conductive region 150 having a length 155 and a conductive region 160 having a length 165. The lengths 155 and 165 are two different gate lengths of the multi-length gate electrode 140. The length 155 or 165 may be the distance along the Y axis between a source region and a drain region in a semiconductor structure 130 or may be the length of a channel region in a semiconductor structure 130. The two lengths 155 and 165 are different. The length 165 is greater than the length 155. In some embodiments, the length 165 is greater by approximately 0.5 to 3 nm. Even though not illustrated in FIG. 1, the dimension of a portion of the dielectric layer under the conductive region 150 along the Z axis may be smaller than the corresponding dimension of another portion of the dielectric layer under the conductive region 160 along the Z axis. In some embodiments, the multi-length gate electrode 140 may include more than two different gate lengths.

The multi-length gate electrode 140 includes one or more conductive materials, such as metal, polycrystalline silicon, other types of conductive materials, or some combination thereof. In some embodiments, the choice of the conductive materials in the multi-length gate electrode 140 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the multi-length gate electrode 140 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer.

The multi-length gate electrode 140 may be electrically coupled to a power plane, ground plane, or signal plane for facilitating power supply or signal transmission of the transistors. A power plane, ground plane, or signal plane may be a metal layer (or part of a metal layer, e.g., a metal track) that may be over the multi-length gate electrode 140 along the Z axis, e.g., either above the multi-length gate electrode 140 (e.g., a frontside metal layer) or below the support structure 110 (e.g., a backside metal layer). Even though not shown in FIG. 1, the IC device 100 may include one or more other gate electrodes, which may be multi-length gate electrodes. A gate electrode may be a dummy gate electrode, which may not be coupled to any power plane, ground plane, or signal plane.

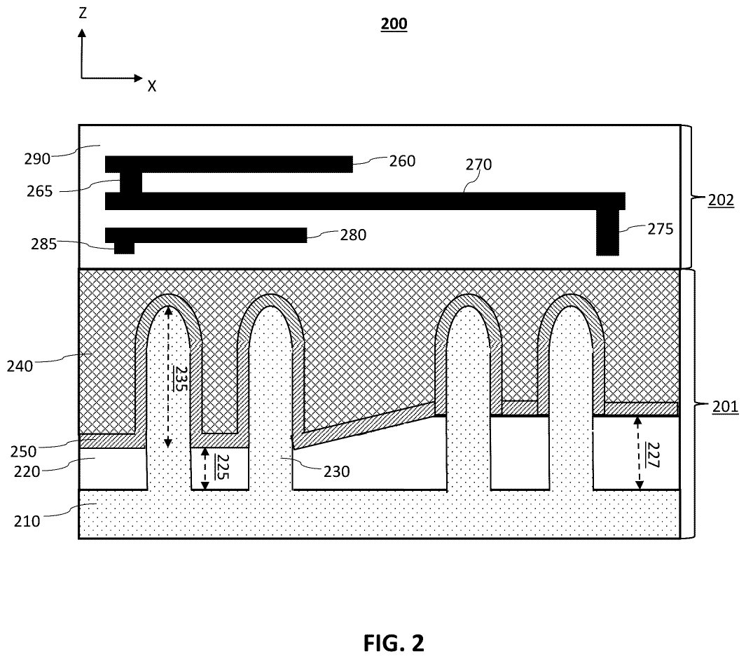

FIG. 2 illustrates an IC device 200 with a FEOL section 201 with a multi-length gate electrode and a BEOL section 202, according to some embodiments of the disclosure. For the purpose of illustration, FIG. 2 shows a cross-sectional view of the IC device 200 in the X-Z plane. The FEOL section 201 includes a support structure 210, a dielectric layer 220, semiconductor structures 230, a gate electrode 240, and a gate insulator 250. The BEOL section 202 includes metal layers 260, 270, and 280, and vias 265, 275, and 285, and an electrical insulator 290. In other embodiments, the IC device 200 may include fewer, more, or different components. For instance, the FEOL section 201 may include more transistors or other types of semiconductor devices, such as resistor, capacitor, inductor, etc. Also, the BEOL section 202 may include a different number of metal layers or a different number of vias.

The support structure 210 includes one or more semiconductor materials. In some embodiments, the support structure 210 may be a semiconductor substrate. The support structure 210 may be an embodiment of the support structure 110 in FIG. 1. The dielectric layer 220 includes one or more dielectric materials, such as oxide. The dielectric layer 220 may be an embodiment of the dielectric layer 220 in FIG. 1. As shown in FIG. 2, the dielectric layer 220 has two different depths 225 and 227 along the Z axis. The depth 225 is smaller than the depth 227. In some embodiments, the difference between the two depths 225 and 227 may be in a range from approximately 1 nm to approximately 10 nm.

The semiconductor structures 230 are over the support structure 210. In some embodiments, the semiconductor structures 230 may be formed based on the support structure 210, e.g., through an epitaxial deposition process. A semiconductor structure 230 may provide the source region, drain region, and channel region of at least one transistor. For instance, a portion of the semiconductor structure 230 that is under the gate electrode 240 may be a channel region. The regions surrounding the channel region may be the source region and drain region. An embodiment of the semiconductor structure 230 may be one of the semiconductor structures 130 in FIG. 1.

The gate electrode 240 is electrically conductive. As shown in FIG. 2, the gate electrode 240 at least partially wraps around the semiconductor structures 230. Various portions of the gate electrode 240 are over the semiconductor structures 230. Other portions of the gate electrode 240 are over the dielectric layer 220. The gate electrode 240 may have multiple different lengths. In some embodiment, the length of the portion of gate electrode 240 above the portion of the dielectric layer 220 having the height 225 is smaller than the length of the portion of gate electrode 240 above the portion of the dielectric layer 220 having the height 227. An embodiment of the gate electrode 240 may be the multi-length gate electrode 140 in FIG. 1.

In some embodiments, the height 225 may be larger than a height 235 of an active portion of a semiconductor structure 230, e.g., the portion that is surrounded by the gate electrode 240. The height 225 may be approximately twice the height 235. In an example, the height 225 may be approximately 100 nm, and the height 235 may be in a range from approximately 40 nm to 60 nm.

The semiconductor structures 230 are also partially wrapped around by the gate insulator 250. The gate insulator 250 separates the semiconductor structures 230 from the gate electrode 240. As shown in FIG. 2, the gate insulator 250 is between each semiconductor structure 230 and the gate electrode 240. In some embodiments, the thickness of the gate insulator 250 above different semiconductor structures 230 (or below different portions of the gate electrode 240) may be different. For instance, the thickness of the gate insulator 250 under the portion of the gate electrode 240 having a larger length may be smaller than the thickness of the gate insulator 250 under the portion of the gate electrode 240 having a smaller length. The gate insulator 250 includes one or more electrical insulators, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

The metal layers 260, 270, and 280 may facilitate supply of electrical signals to transistors or other devices (e.g., diodes, power sources, resistors, capacitors, inductors, sensors, transceivers, receivers, antennas, etc.) in the FEOL section 201. In some embodiments, at least one of the metal layers 260, 270, and 280 may be electrically coupled to the gate electrode 240 for power supply or signal transmission. Even though not shown in FIG. 2, a metal layer 260, 270, or 280 may be electrically coupled to a trench electrode over a source region or drain region of a semiconductor structure 230. A metal layer 260, 270, or 280 may have one or more electrical conductive materials, such as metal. A metal layer 260, 270, or 280 may include one or more metal tracks that are in parallel with each other and separated from each other by the electrical insulator 290. In some embodiments, the metal layer 260 may be M2, the metal layer 270 may be M1, and the metal layer 280 may be M0. A metal track in the metal layer 260 may have a longitudinal axis substantially perpendicular to the longitudinal axis of a metal track in the metal layer 270 or 280. A metal track in the metal layer 270 may have a longitudinal axis substantially perpendicular to the longitudinal axis of a metal track in the metal layer 280.

The vias 265, 275, and 285 may provide conductive channels between the metal layer 260, 270, and 280, or between at least one of the metal layers 260, 270, and 280 with a device or structure in the FEOL section 201. Each of the vias 265, 275, and 285 may include one or more electrically conductive materials, such as metal. Examples of metal include tungsten (W), molybdenum (Mo), ruthenium (Ru), or other metals.

The metal layers 260, 270, and 280 and the vias 265, 275, and 285 may be partially or wholly surrounded by the electrical insulator 290. Certain portions of the metal layers 260, 270, and 280 and the vias 265, 275, and 285 may be insulated by the electrical insulator 290. The electrical insulator 290 may include one or more electrical insulators. An electrical insulator may be a dielectric material, hysteretic material, and so on. Example dielectric material includes oxide (e.g., Si based oxides, metal oxides, etc.), low-k dielectric, high-k dielectric, and so on. Example hysteretic material include ferroelectric materials, antiferroelectric materials, etc.

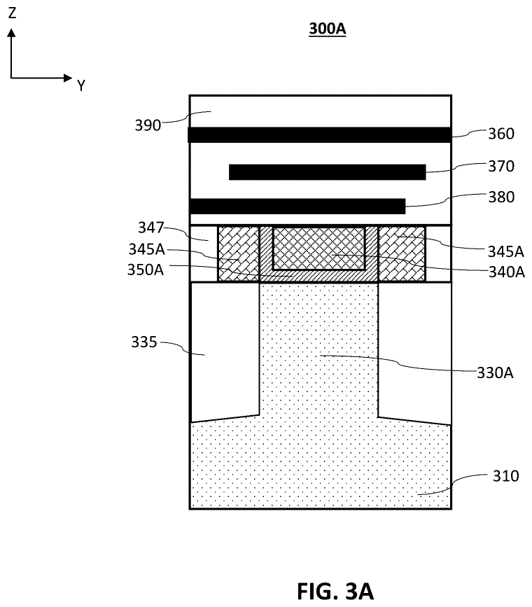

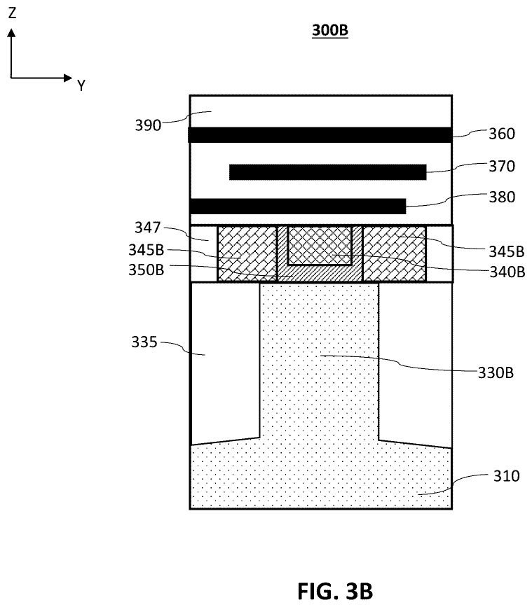

FIGS. 3A and 3B are cross-sectional views of an IC device with a multi-length gate electrode 330, according to some embodiments of the disclosure. FIG. 3A shows a cross-section 300A of the IC device. FIG. 3B shows a cross-section 300B of the IC device. The cross-sections 300A and 300B may be substantially parallel to the Y-Z plane. The cross-section 300A may be at a portion of the multi-length gate electrode that has a larger than nominal gate length, and the cross-section 300B may be at a portion of the multi-length gate electrode that has the nominal gate length. For the purpose of illustration, FIGS. 3A and 3B may not show all the components of the IC device 300.

The cross-section 300A reveals a support structure 310, a semiconductor structures 330A, an electrical insulator 335, a conductive structure 340A, dielectric structures 345A (individually referred to as “dielectric structure 345A”), an electrical insulator 347, a gate insulator 350A, metal layers 360, 370, and 380, and an electrical insulator 390. The cross-section 300B reveals the support structure 310, a semiconductor structures 330B, the electrical insulator 335, a conductive structure 340B, dielectric structures 345B (individually referred to as “dielectric structure 345B”), the electrical insulator 347, a gate insulator 350B, the metal layers 360, 370, and 380, and the electrical insulator 390. In other embodiments, different, fewer, or more components of the IC device 300 may be visible in the cross-section 300A or 300B.

The support structure 310 may be an embodiment of the support structure 110 in FIG. 1 or the support structure 210 in FIG. 2. The semiconductor structures 330A and 330B may be formed based on the support structure 310. The semiconductor structures 330A and 330B may be separated from each other, e.g., by a STI structure, such as the dielectric structure 145 in FIG. 1. In some embodiments, the semiconductor structures 330A and 330B may be substantially in parallel. An embodiment of the semiconductor structure 330A or 330B may be one of the semiconductor structures 130 in FIG. 1 or one of the semiconductor structures 230 in FIG. 2. The metal layer 360, 370, or 380 may be an embodiment of the metal layer 260, 270, or 280 in FIG. 2. The electrical insulator 390 may be an embodiment of the electrical insulator 290 in FIG. 2.

The conductive structures 340A and 340B are two different portions of the multi-length gate electrode. The length of the conductive structure 340A along the Y axis is larger than the length of the conductive structure 340B along the Y axis. In some embodiments, the difference between the two lengths may be up to approximately 3 nm. The length difference may be no less than 0.5 nm. In some embodiments, the conductive structures 340A and 340B may be separate structures. Also, the conductive structures 340A and 340B may have different conductive materials. In other embodiments, the multi-length gate electrode may be an integrated structure.

The conductive structure 340A is between the two dielectric structures 345A. Similarly, the conductive structure 340B is between the two dielectric structures 345B. A dielectric structure 345A or 345B may include one or more dielectric materials, e.g., oxide. A dielectric structure 345A or 345B may be a gate spacer. In some embodiments, a pair of a dielectric structure 345A and a dielectric structure 345B may be portions of an integrated dielectric structure. As shown in FIGS. 3A and 3B, the length of a dielectric structure 345A along the Y axis is smaller than the length of a dielectric structure 345B along the Y axis.

In some embodiments, the lengths of the dielectric structures 345A and 345B may be modulated to get desirable lengths of the conductive structures 340A and 340B. For instance, a dielectric structure 345A or 345B may be formed by etching a pre-formed dielectric structure, e.g., through dry clean. More etching steps may be used to form the dielectric structures 345A than the dielectric structures 345B to achieve smaller lengths of the dielectric structures 345A. Further, the conductive structure 340A is formed in the gap between the dielectric structures 345A, and the conductive structure 340B is formed in the gap between the dielectric structures 345B.

The gate insulator 350A separates the conductive structure 340A from the semiconductor structure 330A. In the embodiments of FIG. 3A, the gate insulator 350A wraps around the conductive structure 340A and separates the conductive structure 340A from the dielectric structures 345A. In other embodiments, the gate insulator 350A may not be present between the conductive structure 340A and the dielectric structures 345A. Similarly, the gate insulator 350B separates the conductive structure 340B from the semiconductor structure 330B. In the embodiments of FIG. 3B, the gate insulator 350B wraps around the conductive structure 340B and separates the conductive structure 340B from the dielectric structures 345B. In other embodiments, the gate insulator 350B may not be present between the conductive structure 340B and the dielectric structures 345B.

As shown in FIGS. 3A and 3B, the dimension along the Z axis of the portion of the gate insulator 350A between the conductive structure 340A and the semiconductor structure 330A is smaller than the corresponding dimension the portion of the gate insulator 350A between the conductive structure 340A and the semiconductor structure 330A. In some embodiments, the smaller dimension of the gate insulator 350A may be caused by the extra etching steps used to form the dielectric structures 345A. The gate insulator 350A or 350B may include one or more electrical insulators. The gate insulator 350A or 350B may be an embodiment of the gate insulator 250 in FIG. 2.

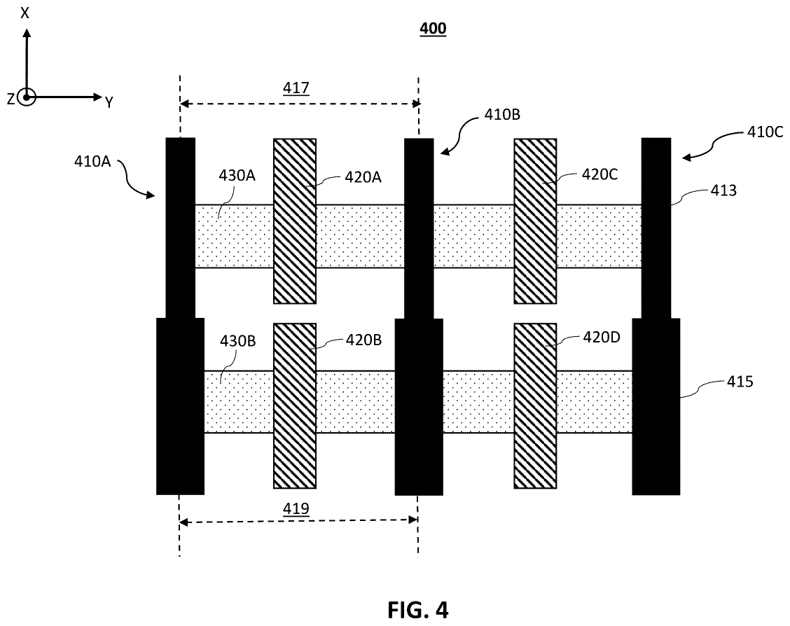

FIG. 4 is a top view of an IC device 400 with multi-length gate electrodes 410A-440C, according to some embodiments of the disclosure. The multi-length gate electrodes 410A-440C are collectively referred to as “multi-length gate electrodes 410” or “multi-length gate electrode 410.” The IC device 400 also includes trench electrodes 420A-420D (collectively referred to as “trench electrodes 420” or “trench electrode 420”) and semiconductor structures 430A and 430B. The IC device 400 may include different, fewer, or more components. For instance, the IC device 400 may include a different number of semiconductor structure, trench electrode, or gate electrode. For the purpose of illustration, FIG. 4 may not show all the components of the IC device 400.

The multi-length gate electrodes 410 are stacked along the horizontal axis of the IC device 400, which may be substantially parallel to the Y axis. A multi-length gate electrode 410 may be an embodiment of the multi-length gate electrode 140 in FIG. 1, the gate electrode 240 in FIG. 2, or the multi-length gate electrode including the conductive structures 340A and 340B in FIG. 3. Each multi-length gate electrode 410 includes two portions 413 and 415. As shown in FIG. 4, the portion 413 has a larger dimension along the Y axis than the portion 415. In some embodiments, at least one of the multi-length gate electrodes 410 is coupled to a power plane, ground plane, or signal plane. For instance, the multi-length gate electrode 410B may be coupled to a power plane, ground plane, or signal plane. The multi-length gate electrodes 410A or 410C may be a dummy gate electrode.

The distance between any two adjacent ones of the multi-length gate electrodes 410 (e.g., the distance between the multi-length gate electrodes 410A and 410B or the distance between the multi-length gate electrodes 410B and 410C) may be a gate pitch in the IC device 400. Despite that the portion 413 and the portion 415 have different lengths, the gate pitch 417 at the portion 413 and the gate pitch 419 at the portion 415 are the same or substantially similar. The gate pitch 417 may be the distance along the Y axis from the center of the portion 413 of a multi-length gate electrode 410 to a center of the portion 413 of the adjacent multi-length gate electrode 410. The gate pitch 419 may be the distance along the Y axis from the center of the portion 415 of a multi-length gate electrode 410 to a center of the portion 415 of the adjacent multi-length gate electrode 410.

The trench electrodes 420 may be conductive structures. A trench electrode 420 may be over the source region or drain region of a transistor in the IC device 400 along the Z axis. A trench electrode 420 may be electrically coupled to a power plane, ground plane, or signal plane. In some embodiments, two or more trench electrodes 420 may be at the same electrical potential. For instance, two or more trench electrodes 420 may be electrically coupled or constitute a single electrode. A trench electrode 420 may also be referred to as a trench contact. A trench electrode 420 over a source region may also be referred to as a source electrode or source contact. A trench electrode 420 over a drain region may also be referred to as a drain electrode or drain contact.

The semiconductor structures 430A and 430B are stacked along the vertical axis of the IC device 400, which may be substantially parallel to the X axis. An embodiment of the semiconductor structure 430A or 430B may be one of the semiconductor structures 130 in FIG. 1, one of the semiconductor structures 230 in FIG. 2, or the semiconductor structure 330A or 330B in FIG. 3.

The multi-length gate electrodes 410, trench electrodes 420, and semiconductor structures 430A and 430B can form transistors in the IC device. For instance, the portion 413 of the multi-length gate electrode 410B, the trench electrodes 420A and 420C, and portions of the semiconductor structure 430A under the portion 413 of the multi-length gate electrode 410B and the trench electrodes 420A and 420C may constitute a transistor. The portion 415 of the multi-length gate electrode 410B, the trench electrodes 420B and 420D, and portions of the semiconductor structure 430B under the portion 415 of the multi-length gate electrode 410B and the trench electrodes 420B and 420D may constitute another transistor. The portion of the semiconductor structure 430A or 430B under a trench electrode 420 may be a source region or drain region. The portions of the semiconductor structure 430A or 430B under the multi-length gate electrode 410B may be the channel regions of the transistors. In other embodiments, the IC device 400 may include one or more additional transistors.

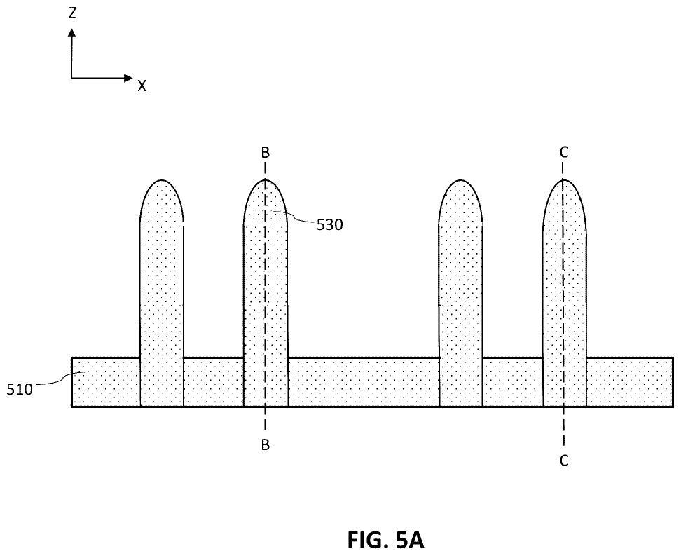

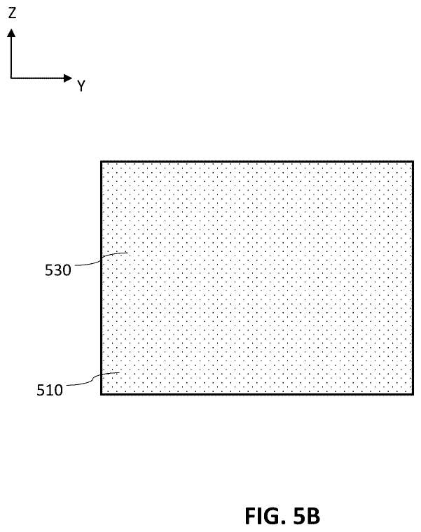

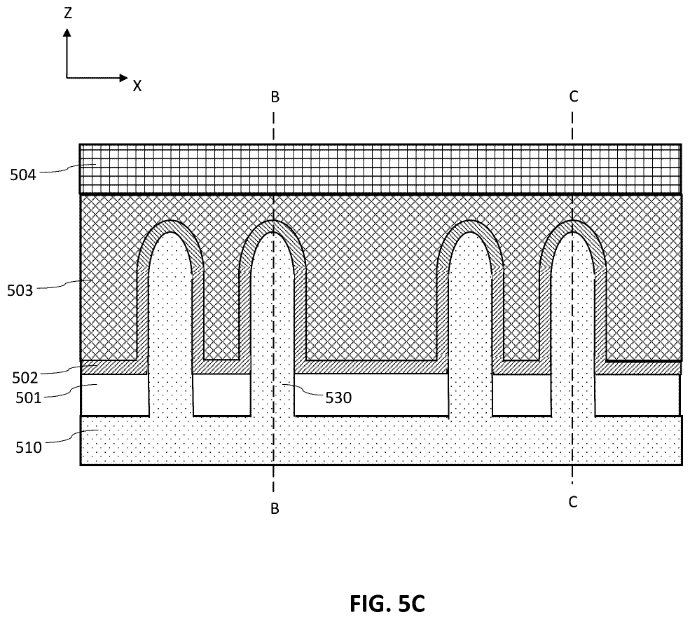

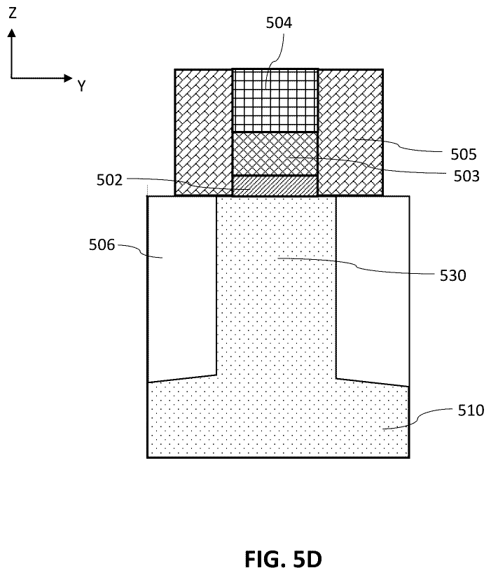

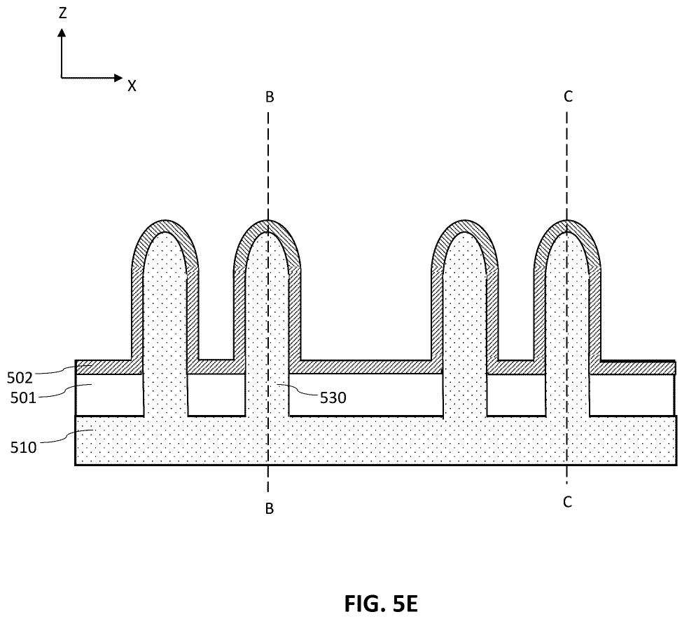

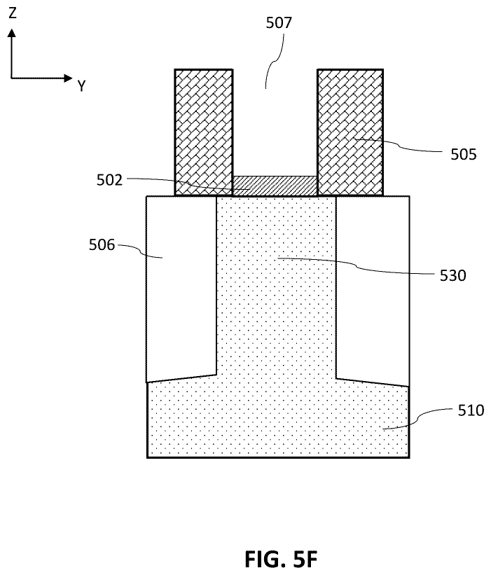

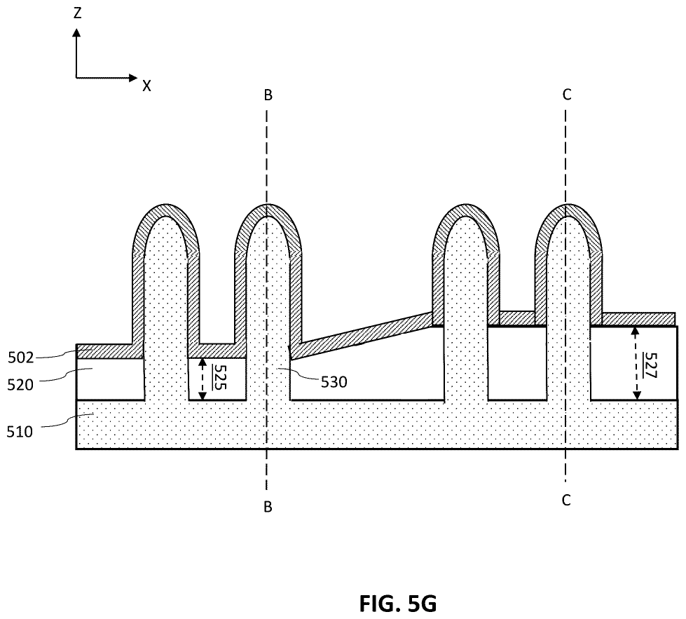

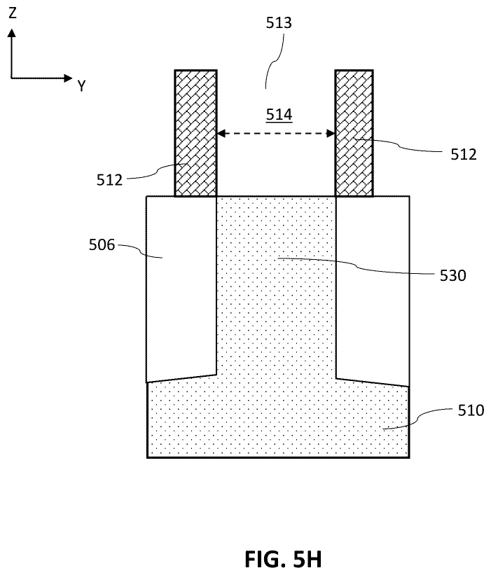

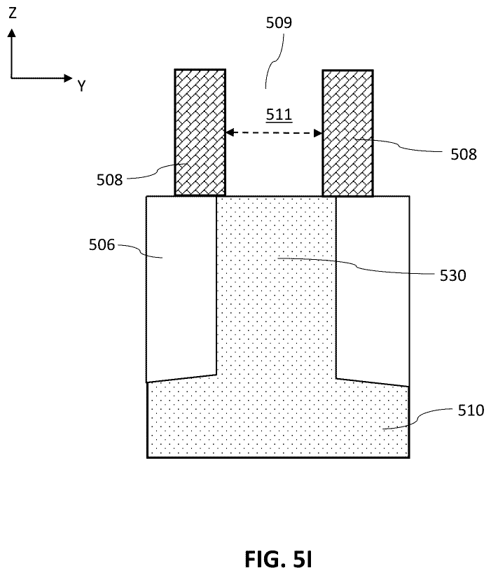

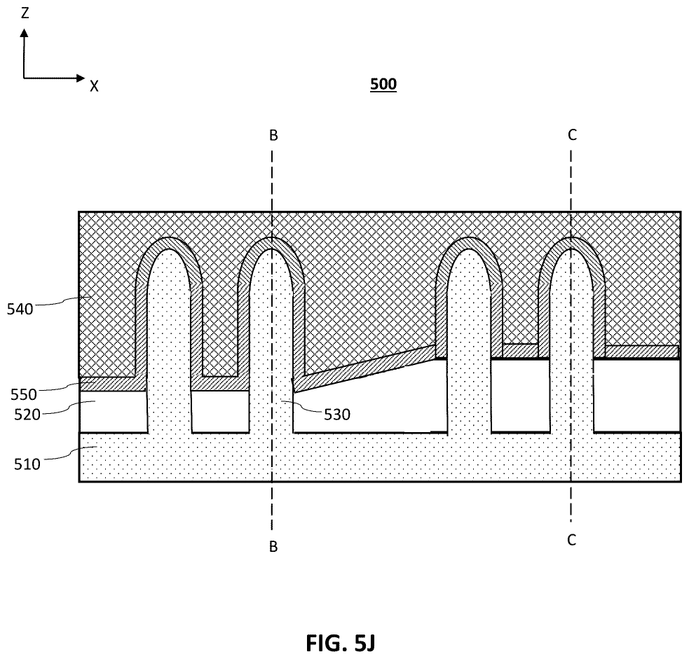

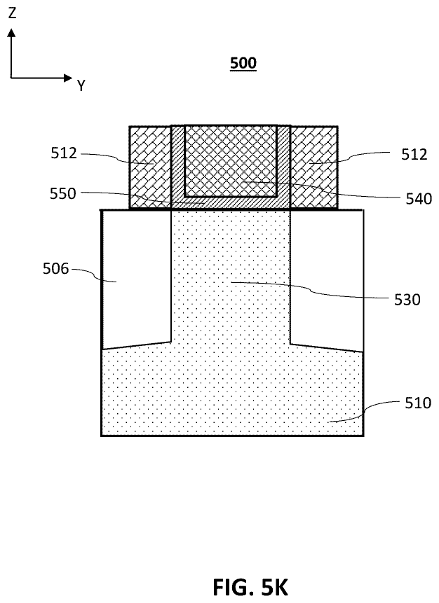

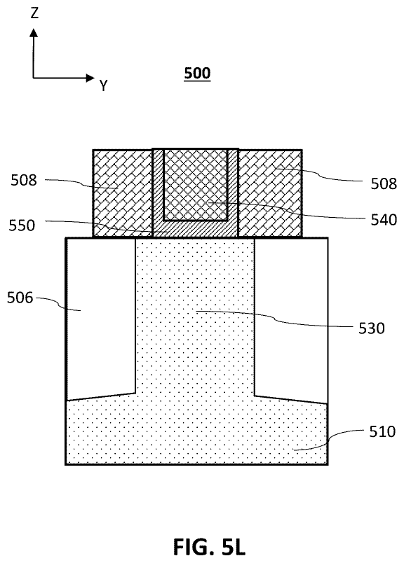

FIGS. 5A-5L illustrate a process of fabricating an IC device with a multi-length gate electrode, according to some embodiments of the disclosure. The IC device may be an embodiment of the IC device 100 in FIG. 1, the IC device 200 in FIG. 2, the IC device in FIG. 3, or the IC device 400 in FIG. 4.

The sequence of the process shown in FIGS. 5A-5L may not represent the order in which the components of the IC device 500 are formed. For instance, a component shown in a figure may be formed before a component shown in a previous figure. Although the process is described with reference to FIGS. 5A-5L, other processes for forming IC devices with multi-length gate electrodes may be alternatively used. For instance, some of the steps described in conjunction with FIGS. 5A-5L may be changed, eliminated, divided, or combined.

FIGS. 5A and 5B illustrate formation of semiconductor structures 530 (individually referred to as “semiconductor structure 530”). FIG. 5B shows a cross-section in the B-B plane or C-C plane shown in FIG. 5A. In FIGS. 5A and 5B, the semiconductor structures 530 are formed over a substrate 510. The semiconductor structures 530 may be formed through an epitaxial deposition process. For instance, one or more semiconductor materials may be deposited onto a surface of the substrate 510. The semiconductor structures 530 may be formed through epitaxial growth of the one or more semiconductor materials. An embodiment of the substrate 510 may be the support structure 110, 210, or 310. An embodiment of a semiconductor structure 530 may be one of the semiconductor structures 130, the semiconductor structures 230, the semiconductor structures 330A and 330B, and the semiconductor structures 430A and 430B.

FIGS. 5C and 5D illustrate formation of a dielectric layer 501, a electrical insulator 502, a dummy gate electrode 503, a hard mask 504, and a gate spacer 505. FIG. 5D shows a cross-section in the B-B plane or C-C plane shown in FIG. 5C. In FIGS. 5C and 5D, the dielectric layer 501 is formed over the substrate 510. The dielectric layer 501 may include dielectric structures that separate the semiconductor structures 530 from each other. A dielectric structure may function as STI. A dielectric structure may be formed by creating a trench in the substrate 510 and depositing one or more dielectric materials into the trench. The electrical insulator 502 is formed to wrap around the semiconductor structures 530 at least partially. The electrical insulator 502 may include one or more electrical insulators. The dummy gate electrode 503 is formed over the gate insulator 502, e.g., by depositing metal onto the gate insulator 502. Also, the hard mask 504 is formed over the dummy gate electrode 503. The hard mask 504 may include one or more dielectric materials with desirable mechanical properties, such as nitride. The gate spacer 505 may surround the dummy gate electrode 503. At least part of a semiconductor structure may be surrounded by an electrical insulator 506.

FIGS. 5E and 5F illustrate removal of the dummy gate electrode 503 and hard mask 504. FIG. 5F shows a cross-section in the B-B plane or C-C plane shown in FIG. 5E. In some embodiments, the dummy gate electrode 503 may be removed after an electrical insulator is provided, e.g., over the source/drain regions of the semiconductor structures 530. The gate spacer 505 is therefore exposed. The gate spacer 505 surrounds a trench 507.

FIGS. 5G-5I illustrate a process of thinning the gate spacer 505. FIG. 5H shows a cross-section in the B-B plane shown in FIG. 5G. FIG. 5I shows a cross-section in the C-C plane shown in FIG. 5G. The gate spacer 505 may be thinned by using dry clean. The process may include multiple dry clean steps. A portion of the gate spacer 505 may go through less dry clean steps than another portion of the gate spacer 505. For instance, the entire gate spacer 505 may be thinned in the first dry clean step, and a part of the gate spacer 505 may be further thinned in the second dry clean step (optionally one or more subsequent dry clean steps). In each dry clean step, the inner side wall of the gate spacer (e.g., the side wall facing the trench 507) is trimmed and a portion of the gate spacer is removed. The cross-section in FIG. 5H is in the portion that has gone through more dry clean steps, and the cross-section in FIG. 5I is in the portion that has gone through less dry clean steps. In FIG. 5I, the gate spacer 505 is thinned to become a gate spacer 508, and the trench 507 is expanded to become a trench 509 having a length 511 along the Y axis. In FIG. 5H, the gate spacer 505 is thinned to become a gate spacer 512, and the trench 507 is expanded to become a trench 513 having a length 514 along the Y axis. The length 514 is greater than the length 511. In some embodiments, the length 514 is greater than the length 511 by up to approximately 3 nm.

The process also removes the electrical insulator 502 in the embodiments of FIGS. 5G-5I. In other embodiments, part or all of the electrical insulator 502 may still be present after the process. For instance, certain regions of the electrical insulator 502 may be blocked during the process, e.g., for thick gate insulator device using the electrical insulator 502 as the initial gate insulator. The process may change the dielectric layer 501 to 520. The portion of the dielectric layer 501 under the portion of the gate spacer 505 going through more dry clean steps has a more significant recess than the portion of the dielectric layer 501 under the portion of the gate spacer 505 going through less dry clean steps. As a result, the dielectric layer 501 has two different dimensions 515 and 527 along the Z axis.

FIGS. 5J-5L illustrate a process of forming a gate electrode 540 and a gate insulator 550. FIG. 5K shows a cross-section in the B-B plane shown in FIG. 5J. FIG. 5L shows a cross-section in the C-C plane shown in FIG. 5J. The gate electrode 540 may be formed by providing one or more conductive materials into at least the trenches 509 and 513. As the trenches 509 and 513 have different lengths, different portions of the gate electrode 540 have different lengths. The length of the gate electrode 540 in the cross-section shown in FIG. 5K is greater than the length of the gate electrode 540 in the cross-section shown in FIG. 5L. Even though the gate electrode 540 has multiple different lengths, the gate pitch of the IC device 500 may be the same or substantially similar. In some embodiments, the gate electrode 540 may wrap the semiconductor structures 530 at least partially. The gate insulator 550 may wrap the gate electrode 540 at least partially. The gate insulator 550 may include a part of the electrical insulator 502. Even though not shown in FIGS. 5A-5L, the IC device 500 may include one or more additional components that can be formed after the process in FIGS. 5J-5L. Even though FIGS. 5A-5L show a process of forming two different gate lengths, more than two different gate lengths may be formed by using the process.

FIGS. 6A-6B are top views of a wafer 2000 and dies 2002 that may facilitate one or more IC devices with multi-length gate electrodes, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including multi-length gate electrodes as described herein). After the fabrication of the semiconductor product is complete (e.g., after manufacture of IC devices with multi-length gate electrodes as described herein), the wafer 2000 may undergo a singulation process in which each of the dies 2002 is separated from one another to provide discrete “chips” of the semiconductor product. In particular, IC devices with multi-length gate electrodes as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the Ill-N diodes with N-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices with multi-length gate electrodes, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

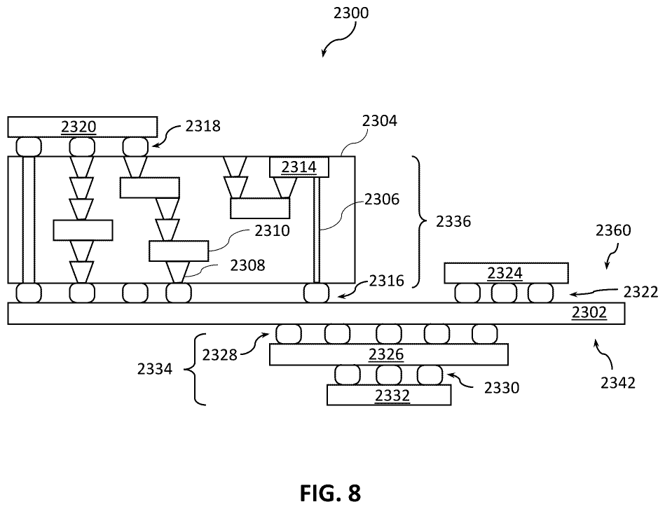

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may facilitate any of the embodiments of IC devices with multi-length gate electrodes. In embodiments in which the IC package 2200 includes multiple dies 2256, the IC package 2200 may be referred to as a multi-chip package. Importantly, even in such embodiments of an MCP implementation of the IC package 2200, one or more IC devices with multi-length gate electrodes may be provided in a single chip, in accordance with any of the embodiments described herein. The dies 2256 may include circuitry to perform any desired functionality. For example, one or more of the dies 2256 may be ESD protection dies, including one or more IC devices with multi-length gate electrodes described herein, one or more of the dies 2256 may be logic dies (e.g., silicon-based dies), one or more of the dies 2256 may be memory dies (e.g., high bandwidth memory), etc. In some embodiments, any of the dies 2256 may include one or more IC devices with multi-length gate electrodes, e.g., as discussed above; in some embodiments, at least some of the dies 2256 may not include any III-N diodes with N-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices with multi-length gate electrodes, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with multi-length gate electrodes in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include one or more IC devices with multi-length gate electrodes in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 8), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device of FIGS. 1-2), or any other suitable component. In particular, the IC package 2320 may include one or more IC devices with multi-length gate electrodes as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices having multi-length gate electrodes as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

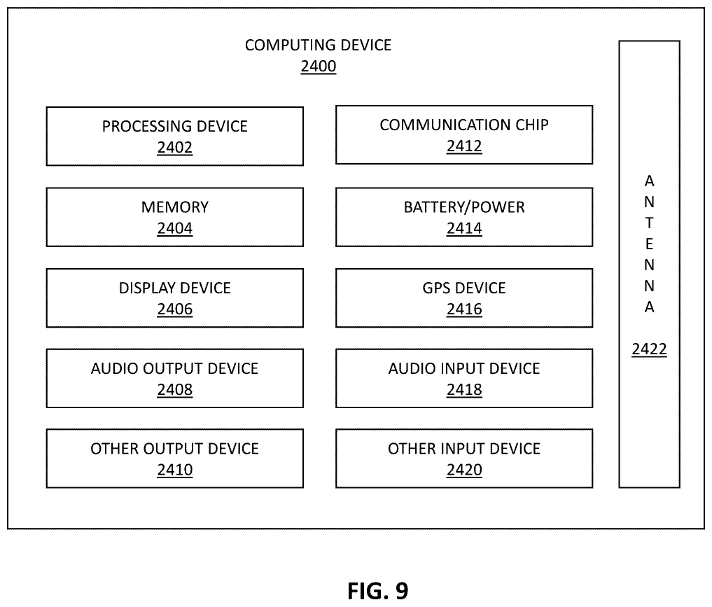

FIG. 9 is a block diagram of an example computing device 2400 that may include one or more components with one or more IC devices with multi-length gate electrodes, according to some embodiments of the disclosure. For example, any suitable ones of the components of the computing device 2400 may include a die (e.g., the die 2002 of FIG. 6B) including one or more IC devices with multi-length gate electrodes, according to some embodiments of the disclosure. Any of the components of the computing device 2400 may include one or more IC devices with multi-length gate electrodes (e.g., any embodiment of IC devices with multi-length gate electrodes described above in conjunction with FIGS. 1, 2, 4, and 5) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices having multi-length gate electrodes as described herein may be particularly advantageous for use as part of ESD circuits protecting power amplifiers, low-noise amplifiers, filters (including arrays of filters and filter banks), switches, or other active components. In some embodiments, IC devices having multi-length gate electrodes as described herein may be used in PMICs, e.g., as a rectifying diode for large currents. In some embodiments, IC devices having multi-length gate electrodes as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first conductive structure having a first longitudinal axis; a second conductive structure having a second longitudinal axis that is substantially parallel to the first longitudinal axis; a first semiconductor structure; and a second semiconductor structure over the first semiconductor structure, where: a first portion of the first conductive structure is over a portion of the first semiconductor structure, a second portion of the first conductive structure is over a portion of the second semiconductor structure, a dimension of the first portion in a direction substantially perpendicular to the first longitudinal axis is greater than a dimension of the second portion in the direction, and a distance from a center of the first portion to the second longitudinal axis is the same or substantially similar as a distance from a center of the second portion to the second longitudinal axis.

Example 2 provides the IC device according to example 1, where a difference between the dimension of the first portion and the dimension of the second portion is up to approximately 3 nanometers.

Example 3 provides the IC device according to example 2, where the difference between the dimension of the first portion and the dimension of the second portion is at least approximately 0.5 nanometer.

Example 4 provides the IC device according to any of the preceding examples, further including a first dielectric structure over the first portion of the first conductive structure in the direction; and a second dielectric structure over the second portion of the first conductive structure in the direction, where a dimension of the first dielectric structure in the direction is smaller than a dimension of the second dielectric structure in the direction

Example 5 provides the IC device according to any of the preceding examples, further including a first dielectric structure at least partially between the first portion of the first conductive structure and the portion of the first semiconductor structure; and a second dielectric structure at least partially between the second portion of the first conductive structure and the portion of the second semiconductor structure, where a dimension of the first dielectric structure in the direction is smaller than a dimension of the second dielectric structure in the direction.

Example 6 provides the IC device according to any of the preceding examples, further including a first dielectric region over the first portion of the first conductive structure in a different direction that is substantially perpendicular to the direction and the first longitudinal axis; and a second dielectric region over the second portion of the first conductive structure in the different direction, where a dimension of the first dielectric region is smaller than a dimension of the second dielectric region.

Example 7 provides the IC device according to any of the preceding examples, where the first semiconductor structure has a fin or nanoribbon.

Example 8 provides an IC device, including a first transistor including a first source region, a first drain region, and a first channel region, where the first source region is over the first drain region along a horizontal axis of the IC device; a second transistor over the first transistor along a vertical axis of the IC device, the second transistor including a second source region, a second drain region, and a second channel region; a first gate electrode including a first portion and a second portion, where the first portion is over the first channel region, and the second portion is over the second channel region; and a second gate electrode over the first gate electrode along a horizontal axis of the IC device, where a dimension of the first portion along the horizontal axis is greater than a dimension of the second portion along the horizontal axis, and a distance from the first portion to the second gate electrode along the horizontal axis is the same or substantially similar as a distance from the second portion to the second gate electrode.

Example 9 provides the IC device according to example 8, where the first gate electrode has a longitudinal axis along the vertical axis, and the first source region, a first drain region, and a first channel region are in a semiconductor structure having a longitudinal axis along the horizontal axis.

Example 10 provides the IC device according to example 9, where the semiconductor structure includes a fin or nanoribbon.

Example 11 provides the IC device according to any one of examples 8-10, where the first source region, a first drain region, and a first channel region are in a first semiconductor structure, the second source region, a second drain region, and a second channel region are in a second semiconductor structure, and the first semiconductor structure is over the second semiconductor structure in a direction along the vertical axis.

Example 12 provides the IC device according to any one of examples 8-11, where the second gate includes a third portion and a fourth portion, and a dimension of the third portion along the horizontal axis is greater than a dimension of the fourth portion along the horizontal axis.

Example 13 provides the IC device according to any one of examples 8-12, where a difference between the dimension of the first portion and the dimension of the second portion is in a range from approximately 0.5 nanometer to approximately 3 nanometers.

Example 14 provides the IC device according to any one of examples 8-13, where the first transistor further includes a first gate insulator between the first portion of the first gate electrode and the first channel region; and the second transistor further includes a second gate insulator between the second portion of the first gate electrode and the second channel region, where a dimension of the first gate insulator along the horizontal axis is smaller than a dimension of the second gate insulator along the horizontal axis.

Example 15 provides a method for forming an IC device, including forming a semiconductor structure over a substrate; forming a dielectric structure, the semiconductor structure at least partially surrounded by the dielectric structure; reducing a dimension of a first portion of the dielectric structure to a first predetermined dimension; reducing a dimension of a second portion of the dielectric structure to a second predetermined dimension; and forming a conductive structure, where a first portion of the conductive structure is between a first portion of the semiconductor structure and the first portion of the dielectric structure, and a second portion of the conductive structure is between a second portion of the semiconductor structure and the second portion of the dielectric structure.

Example 16 provides the method according to example 15, where reducing the dimension of the second portion of the dielectric structure to the second predetermined dimension includes reducing the dimension of the second portion of the dielectric structure to the first predetermined dimension; and further reducing the dimension of the second portion of the dielectric structure from the first predetermined dimension to the second predetermined dimension.

Example 17 provides the method according to example 15 or 16, where reducing the dimension of the first portion of the dielectric structure to the first predetermined dimension includes removing a part of the first portion of the dielectric structure by using dry clean.

Example 18 provides the method according to any one of examples 15-17, where reducing the dimension of the second portion of the dielectric structure to the second predetermined dimension includes removing a part of the second portion of the dielectric structure by using dry clean.

Example 19 provides the method according to any one of examples 15-18, where a difference between the first predetermined dimension and the second predetermined dimension is in a range from approximately 0.5 nanometer to approximately 3 nanometers.

Example 20 provides the method according to any one of examples 15-19, where forming the semiconductor structure over the substrate includes forming a fin or nanoribbon including a semiconductor material over the substrate.

Example 21 provides an IC package, including the IC device according to any one of examples 1-14; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-14 may include, or be a part of, at least one of a memory device, a computing device, a wearable device, a handheld electronic device, and a wireless communications device.

Example 24 provides an electronic device, including a carrier substrate; and one or more of the IC devices according to examples 1-14 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 15-20, further including processes for forming the IC device according to any one of claims 1-14.

Example 35 provides the method according to any one of examples 15-20, further including processes for forming the IC package according to any one of the claims 21-23.

Example 36 provides the method according to any one of examples 15-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first conductive structure having a first longitudinal axis;
a second conductive structure having a second longitudinal axis that is substantially parallel to the first longitudinal axis;
a first semiconductor structure; and
a second semiconductor structure over the first semiconductor structure,
wherein:
a first portion of the first conductive structure is over a portion of the first semiconductor structure,
a second portion of the first conductive structure is over a portion of the second semiconductor structure,
a dimension of the first portion in a direction substantially perpendicular to the first longitudinal axis is greater than a dimension of the second portion in the direction, and
a distance from a center of the first portion to the second longitudinal axis is the same or substantially similar as a distance from a center of the second portion to the second longitudinal axis.

2. The IC device according to claim 1, wherein a difference between the dimension of the first portion and the dimension of the second portion is up to approximately 3 nanometers.

3. The IC device according to claim 2, wherein the difference between the dimension of the first portion and the dimension of the second portion is at least approximately 0.5 nanometer.

4. The IC device according to claim 1, further comprising:
a first dielectric structure over the first portion of the first conductive structure in the direction; and
a second dielectric structure over the second portion of the first conductive structure in the direction,
wherein a dimension of the first dielectric structure in the direction is smaller than a dimension of the second dielectric structure in the direction.

5. The IC device according to claim 1, further comprising:
a first dielectric structure at least partially between the first portion of the first conductive structure and the portion of the first semiconductor structure; and
a second dielectric structure at least partially between the second portion of the first conductive structure and the portion of the second semiconductor structure,
wherein a dimension of the first dielectric structure in the direction is smaller than a dimension of the second dielectric structure in the direction.

6. The IC device according to claim 1, further comprising:
a first dielectric region over the first portion of the first conductive structure in a different direction that is substantially perpendicular to the direction and the first longitudinal axis; and
a second dielectric region over the second portion of the first conductive structure in the different direction,
wherein a dimension of the first dielectric region is smaller than a dimension of the second dielectric region.

7. The IC device according to claim 1, wherein the first semiconductor structure has a fin or nanoribbon.

8. An integrated circuit (IC) device, comprising:
a first transistor comprising a first source region, a first drain region, and a first channel region, wherein the first source region is over the first drain region along a horizontal axis of the IC device;
a second transistor over the first transistor along a vertical axis of the IC device, the second transistor comprising a second source region, a second drain region, and a second channel region;
a first gate electrode comprising a first portion and a second portion, wherein the first portion is over the first channel region, and the second portion is over the second channel region; and
a second gate electrode over the first gate electrode along a horizontal axis of the IC device,
wherein a dimension of the first portion along the horizontal axis is greater than a dimension of the second portion along the horizontal axis, and a distance from the first portion to the second gate electrode along the horizontal axis is the same or substantially similar as a distance from the second portion to the second gate electrode.

9. The IC device according to claim 8, wherein:
the first gate electrode has a longitudinal axis along the vertical axis, and
the first source region, a first drain region, and a first channel region are in a semiconductor structure having a longitudinal axis along the horizontal axis.

10. The IC device according to claim 9, wherein the semiconductor structure comprises a fin or nanoribbon.

11. The IC device according to claim 8, wherein:
the first source region, a first drain region, and a first channel region are in a first semiconductor structure,
the second source region, a second drain region, and a second channel region are in a second semiconductor structure, and
the first semiconductor structure is over the second semiconductor structure in a direction along the vertical axis.

12. The IC device according to claim 8, wherein:
the second gate comprises a third portion and a fourth portion, and
a dimension of the third portion along the horizontal axis is greater than a dimension of the fourth portion along the horizontal axis.

13. The IC device according to claim 8, wherein a difference between the dimension of the first portion and the dimension of the second portion is in a range from approximately 0.5 nanometer to approximately 3 nanometers.

14. The IC device according to claim 8, wherein:
the first transistor further comprises a first gate insulator between the first portion of the first gate electrode and the first channel region; and
the second transistor further comprises a second gate insulator between the second portion of the first gate electrode and the second channel region,
wherein a dimension of the first gate insulator along the horizontal axis is smaller than a dimension of the second gate insulator along the horizontal axis.

15. A method for forming an integrated circuit (IC) device, comprising:
forming a semiconductor structure over a substrate;
forming a dielectric structure, the semiconductor structure at least partially surrounded by the dielectric structure;
reducing a dimension of a first portion of the dielectric structure to a first predetermined dimension;
reducing a dimension of a second portion of the dielectric structure to a second predetermined dimension; and
forming a conductive structure,
wherein a first portion of the conductive structure is between a first portion of the semiconductor structure and the first portion of the dielectric structure, and a second portion of the conductive structure is between a second portion of the semiconductor structure and the second portion of the dielectric structure.

16. The method according to claim 15, wherein reducing the dimension of the second portion of the dielectric structure to the second predetermined dimension comprises:
reducing the dimension of the second portion of the dielectric structure to the first predetermined dimension; and
further reducing the dimension of the second portion of the dielectric structure from the first predetermined dimension to the second predetermined dimension.

17. The method according to claim 15, wherein reducing the dimension of the first portion of the dielectric structure to the first predetermined dimension comprises:
removing a part of the first portion of the dielectric structure by using dry clean.

18. The method according to claim 15, wherein reducing the dimension of the second portion of the dielectric structure to the second predetermined dimension comprises:
removing a part of the second portion of the dielectric structure by using dry clean.

19. The method according to claim 15, wherein a difference between the first predetermined dimension and the second predetermined dimension is in a range from approximately 0.5 nanometer to approximately 3 nanometers.

20. The method according to claim 15, wherein forming the semiconductor structure over the substrate comprises:
forming a fin or nanoribbon comprising a semiconductor material over the substrate.
